(19) United States
(12) Patent Application Publication
(10) Pub. No.: US 2026/0343910 A1
(43) Pub. Date: Oct. 29, 2026

(54) METAL-INSULATOR-METAL CAPACITOR WITH PARTIAL BOTTOM LANDING

(71) Applicant: Taiwan Semiconductor Manufacturing Company, Ltd., Hsinchu (TW)

(72) Inventors: Jaio-Wei Wang, Kaohsiung City (TW); Dun-Nian Yaung, Taipei City (TW); Jen-Cheng Liu, Hsin-Chu City (TW); Hsing-Chih Lin, Tainan City (TW); Min-Feng Kao, Chiayi City (TW); Ko Chun Liu, Toufen Township (TW); Meng-Hsien Lin, Tainan City (TW)

(21) Appl. No.: 19/735,610

(22) Filed: Jul. 9, 2026

Related U.S. Application Data
(62) Division of application No. 18/401,749, filed on Jan. 2, 2024.
(60) Provisional application No. 63/611,284, filed on Dec. 18, 2023.

(51) Int. Cl. H10D 1/00; H10D 1/68; H10W 20/42; H10W 42/20

(52) U.S. Cl. CPC H10D 1/042; H10D 1/714; H10D 1/716; H10W 20/42; H10W 42/20

(57) ABSTRACT

Some embodiments relate to an integrated device, including a first contact wire comprising an upper surface over a substrate; a plurality of shielding wires level with the first contact wire and having upper surfaces that are level with the upper surface of the first contact wire; and a first capacitor having an upper layer and a plurality of protrusions including a first protrusion and a second protrusion extending from the upper layer in a first direction towards the shielding wires; wherein the first protrusion extends to the upper surface of the first contact wire; and wherein the second protrusion is over and separated from the shielding wires in the first direction.

### REFERENCE TO RELATED APPLICATIONS

This Application is a Divisional of U.S. Application number Ser. No. 18/401,749, filed on Jan. 2, 2024, which claims the benefit of U.S. Provisional Application number 63/611,284, filed on Dec. 18, 2023. The contents of the above-referenced Patent Applications are hereby incorporated by reference in their entirety.

### BACKGROUND

Capacitors are a passive circuit component used in imaging, memory, and many more applications. One common type of capacitor in use in integrated circuits are metal-insulator-metal (MIM) capacitors. MIM capacitors have a metal bottom layer, a metal top layer, and a dielectric layer separating the two. Three-dimensional MIM capacitors have been fabricated that increase the surface area of the dielectric and surrounding metal layers by extending the capacitor both across an interlayer dielectric (ILD) layer and through the ILD layer in one or more trenches.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a capacitor with protrusions contacting a contact wire of a first wire level and protrusions extending over shielding wires of the first wire level.

FIGS. 2A-2C illustrate cross-sectional views and top views of additional embodiments of a plurality of capacitors with a partial bottom landing on the contact wires.

FIGS. 3-15 illustrate a series of cross-sectional views of some embodiments of a method of forming capacitors with a partial bottom landing on the contact wires.

FIG. 16 illustrates a flowchart of some embodiments of a method of forming capacitors with a partial bottom landing on the contact wires.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An MIM capacitor may comprise a bottom metal layer, a top metal layer, and a capacitor dielectric separating the bottom metal layer from the top metal layer. The MIM capacitor may extend both horizontally across an interlayer dielectric (ILD) layer, or vertically through the ILD layer. The MIM capacitor extending both horizontally and vertically increases the surface area of the capacitor dielectric and the resulting capacitance of the capacitor being formed. In some embodiments, the MIM capacitor has multiple protrusions extending from a bottom side of the capacitor, where the bottom metal layer on the multiple protrusions is coupled to a first wire level. A second wire level is often coupled to the top metal layer.

The change in charge present in the capacitor during operation may result in the capacitor exhibiting a changing electromagnetic field, interfering with the function of underlying semiconductor devices. In some embodiments, to mitigate electromagnetic interference between the capacitors and underlying semiconductor devices, a layer of shielding wires are present beneath the capacitors. The shielding wires are conductive and attenuate the electromagnetic waves released by the capacitor.

However, the addition of the shielding wires introduces an additional metal layer to the integrated device, increasing both the cost and production time of the integrated device. Therefore, a device that comprises three-dimensional MIM capacitors and a layer of shielding wires underlying the MIM capacitors without increasing the number of layers in the device is desirable.

The present disclosure provides an MIM capacitor with a plurality of protrusions overlying a plurality of shielding wires. A contact wire is coupled to a first protrusion of the plurality of protrusions, and is not directly contacting a second protrusion of the plurality of protrusions. That is, the MIM capacitor has a partial bottom landing on the contact wire, in that a first bottom surface of the first protrusion lands on the contact wire, and the second bottom surface of the second protrusion does not land on the contact wire. The second protrusion is spaced from the contact wire and the shield wires by a first etch stop layer. The first protrusion extends to a first depth and the second protrusion extends to a second depth less than the first depth. The difference in depths results in the first protrusion extending to an upper surface of the contact wire and the second protrusion having a bottom surface that is spaced from the upper surface of the contact wire. As such, the contact wire and the shielding wires may be in the same wire level, reducing the number of metal layers used to form the integrated device.

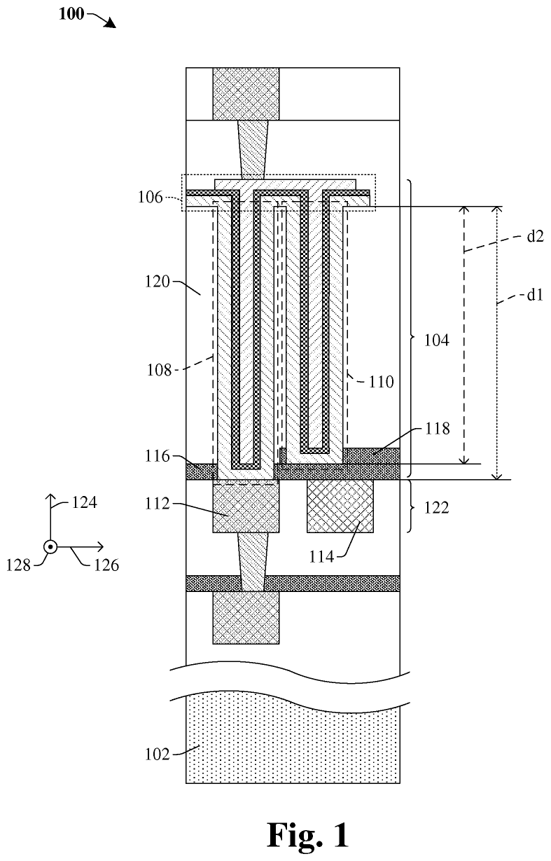

FIG. 1 illustrates a cross-sectional view 100 of some embodiments of a capacitor with protrusions contacting a contact wire of a first wire level and protrusions extending over shielding wires of the first wire level.

As shown in the cross-sectional view 100 of FIG. 1, a first capacitor 104 is over a substrate 102. The first capacitor 104 has an upper layer 106 with a first protrusion 108 and a second protrusion 110 extending from the upper layer 106 in a first direction 124. The first protrusion 108 has a first bottom surface 108b that is at a first depth d1 measured from the upper layer 106. The first bottom surface 108b is contacting a contact wire 112 beneath the first capacitor 104. The second protrusion 110 has a second bottom surface 110b that is at a second depth d2 measured from the upper layer 106. The second depth d2 is than the first depth d1, and the second depth d2 does not extend to the contact wire 112. The second protrusion 110 is directly above a shielding wire 114. The second protrusion 110 is separated from the shielding wire 114 by a first etch stop layer 116. A second etch stop layer 118 contacts outer sidewalls of the second protrusion 110 and is spaced from sidewalls of the first protrusion 108 in a second direction 126 and a third direction 128 perpendicular to the first direction 124.

The first and second protrusions 108, 110 are formed within trenches that are etched into an inter-layer dielectric (ILD) layer 120. The trenches extend into the first and second etch stop layer 116, 118. The addition of the second etch stop layer 118 results in the trench for the second protrusion 110 extending to a lesser depth than the trench for the first protrusion 108. The disparity in depths further results in the first protrusion 108 extending to the contact wire 112, and the second protrusion 110 being vertically spaced from the shielding wire 114 by the first etch stop layer 116, resulting in the capacitor having a partial bottom landing on the contact wire 112. The disparity between the first depth d1 and the second depth d2 prevents the shielding wires from contacting the capacitor, resulting in a design that has both the shielding wire 114 and the contact wire 112 in a first wire level 122. The shielding wires attenuate the electromagnetic waves released by the capacitor during operation, limiting the interference the electromagnetic waves may cause in underlying devices. The configuration of the shielding wire 114 and the contact wire 112 being in the first wire level 122 results in the attenuating properties of the shielding wires being present without increasing the number of wire levels in the design.

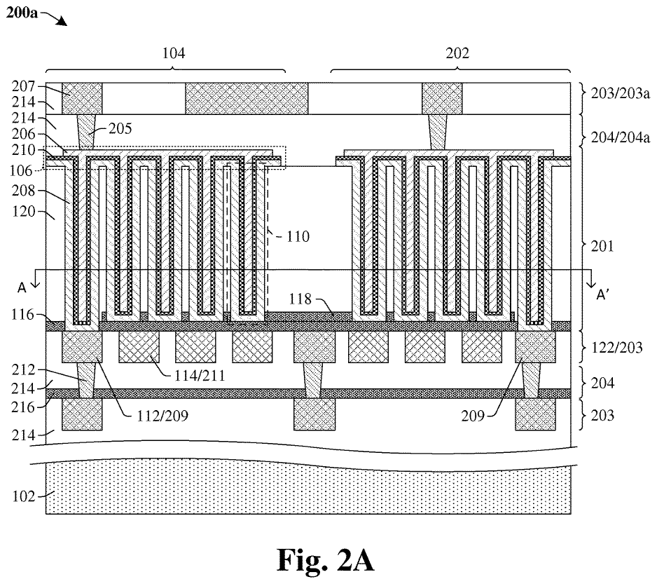

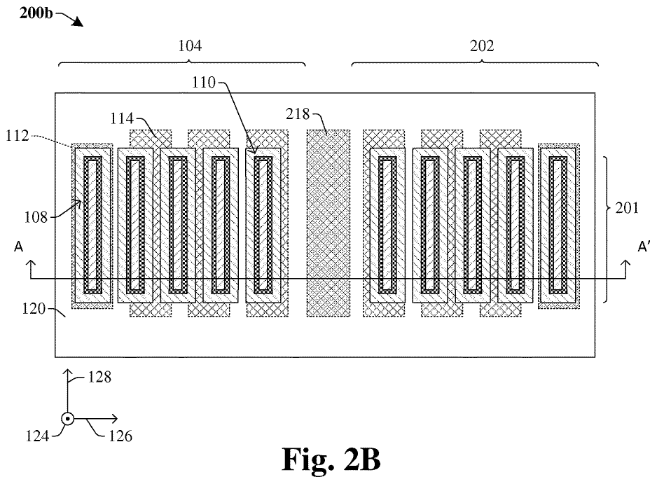

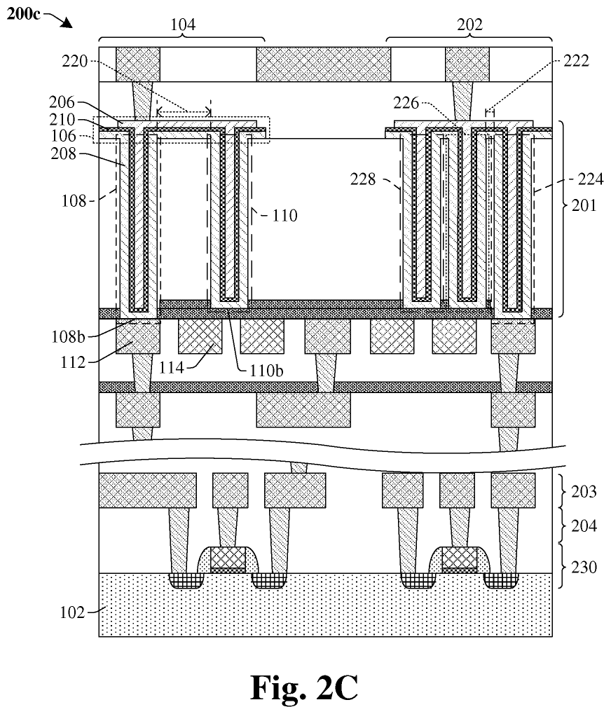

FIGS. 2A-2C illustrate cross-sectional views 200a, 200c and a top view 200b of additional embodiments of a plurality of capacitors with a partial bottom landing on the contact wires. Note that the shielding wire 114, the contact wire 112, and the one or more additional wires 218 are shown in phantom in FIG. 2B for ease of understanding.

In some embodiments, a plurality of capacitors 201 comprising the first capacitor 104 and a second capacitor overly the substrate 102. The plurality of capacitors 201 may respectively comprise a plurality of protrusions extending from upper layers of the plurality of capacitors. A plurality of wire levels 203 and a plurality of via levels 204 extend over and under the plurality of capacitors 201. That is, one or more wire levels and via levels of the plurality of wire levels 203 and the plurality of via levels 204 are above the plurality of capacitors 201, and one or more wire levels and via levels are below the plurality of capacitors 201.

The plurality of capacitors 201 have top metal layers 206, bottom metal layers 208 directly beneath the top metal layers 206, and intermetal dielectrics 210 separating the top metal layers 206 from the bottom metal layers 208 directly beneath the top metal layers 206. A first via level 204a of the plurality of via levels 204 above the plurality of capacitors 201 has vias 205 coupling the top metal layers 206 to wires 207 of a second wire level 203a of the plurality of wire levels 203. The contact wire 112 of the first wire level 122 directly contacts the bottom metal layer 208 of the first capacitor 104. The contact wire 112 is part of a plurality of contact wires 209 that directly contact the bottom metal layers 208 of the plurality of capacitors 201. A plurality of shielding wires 211 comprising the shielding wire 114 extend between the plurality of capacitors 201 and the substrate 102. The plurality of shielding wires 211 are floating. That is, the plurality of shielding wires 211 are not grounded or physically coupled to a voltage source. In some embodiments, the plurality of contact wires 209 are coupled to a wire level of the plurality of wire levels 203 by vias 212 in a via level of the plurality of via levels 204. A plurality of ILD layers 214 surround the plurality of wire levels 203 and the plurality of via levels 204. In some embodiments, etch stop layers 216 extend between the plurality of ILD layers 214.

As shown in the top view 200b of FIG. 2B, in some embodiments, the contact wire 112 extends past outer sidewalls of the first protrusion 108 in the second direction 126 and the third direction 128, entirely covering the first bottom surface (see 108b of FIG. 1). In some embodiments, a set of shielding wires 114 beneath the plurality of capacitors 201 may have different spacing in the second direction 126 between the individual shielding wires than a spacing in the second direction 126 between the plurality of protrusions of the plurality of capacitors 201. In some embodiments, outer sidewalls of the second protrusion 110 extend past outer sidewalls of a shielding wire directly beneath the second protrusion 110 in the second direction 126. That is, in some embodiments, a portion of the second protrusion is not directly over the shielding wires 114. In some embodiments, one or more additional wires 218 extend between the shielding wires 114 beneath the plurality of capacitors 201. The additional wires 218 extend past the plurality of capacitors in the third direction 128 parallel to the direction the shielding wires 114 and the contact wire 112 extends in. The one or more additional wires 218 may couple to devices surrounding the first capacitor 104 and the second capacitor 202, propagating signals between the capacitors and further increasing the versatility of the first wire level (see 122 of FIG. 2A). In some embodiments, the one or more additional wires are not directly beneath the plurality of capacitors 201 That is, the one or more additional wires 218 are laterally offset from the plurality of capacitors 201.

As shown in the cross-sectional view 200c of FIG. 2C, in some embodiments, the first capacitor 104 has a first spacing 220 between the first protrusion 108 and the second protrusion 110. The second capacitor 202 has a second spacing 222 between a first protrusion 224 and a second protrusion 226 of the second capacitor 202. In some embodiments, the first spacing 220 is different from the second spacing 222 (e.g., the first spacing 220 may be greater than the second spacing 222 or less than the second spacing 222). In some embodiments, the first capacitor 104 or the second capacitor 202 may have a third protrusion 228. The third protrusion extends to a substantially equal depth as the second protrusions 226, 110. The plurality of capacitors 201 have a capacitance dependent on a surface area and a thickness of the intermetal dielectric 210 between the top metal layer 206 and the bottom metal layer 208. As the thickness of the intermetal dielectric 210 is similar between different capacitors, and the depths of the second protrusions are substantially equal, the capacitances may be varied by changing the size of the upper layer 106 (potentially resulting in a greater spacing between the first and second protrusions 108, 110). The capacitances may also be varied by forming a different number of protrusions extending from the upper layer 106. These changes alter the surface area, and this the capacitance, of the capacitor, and may be used to have capacitors of different capacitances be formed in conjunction with the partial bottom landing (e.g., the first bottom surface 108b contacting the contact wire 112 and the second bottom surface 110b overlying the shielding wires 114) on the contact wires.

In some embodiments, wires and vias of the plurality of wire levels 203 and the plurality of via levels 204 are further coupled to a plurality of semiconductor devices 230 in the integrated device. In some embodiments, the plurality of semiconductor devices 230 may comprise a transistor device (e.g., a planar FET, a FinFET, a gate-all-around (GAA) device, etc.). The semiconductor devices 230 may be front-end-of-line (FEOL) or back-end-of-line (BEOL) devices. The plurality of semiconductor devices 230, in some embodiments, are coupled to one or more of the capacitors in the plurality of capacitors 201 or the one or more additional wires (see 218 of FIG. 2B)

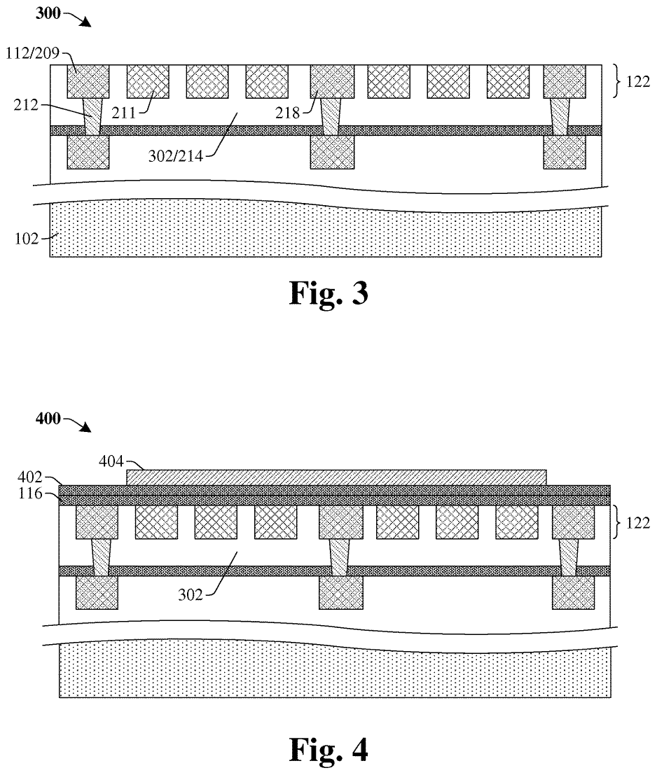

FIGS. 3-15 illustrate a series of cross-sectional views 300-1500 of some embodiments of a method of forming capacitors with a partial bottom landing on the contact wires. Although FIGS. 3-15 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in a top view 300 of FIG. 3, the first wire level 122 comprising the plurality of contact wires 209, the plurality of shielding wires 211, and the one or more additional wires 218 are formed over the substrate 102. The plurality of contact wires 209 comprises the contact wire 112. The substrate 102 may be any suitable type of substrate and/or may, for example, be a semiconductor wafer, one or more dies on a wafer, or any other suitable type of semiconductor body and/or epitaxial layers. In some embodiments, the substrate 102 is or comprises silicon, sapphire, the like, or any combination of the foregoing. In some embodiments, the plurality of contact wires, 209, the shielding wires 211, and the one or more additional wires 218 are or comprise a conductive material, such as copper (Cu), titanium (Ti), aluminum (Al), the like, or a combination of the foregoing. The first wire level 122 is formed within a second ILD layer 302 of the plurality of ILD layers 214. In some embodiments, the second ILD layer 302 is or comprises an insulator, such as silicon dioxide (SiO₂) or the like.

In some embodiments, the first wire level 122 is formed by etching trenches (e.g., using a dry etching process with a hard mask) into the second ILD layer 302, the trenches corresponding to the positions of the wires to be formed. A conformal metal layer is then formed over the second ILD layer 302, filling the trenches previously etched. In some embodiments, the conformal metal layer is formed using atomic layer deposition (ALD), physical vapor deposition (PVD), chemical vapor deposition (CVD), electrochemical plating, electroless plating, some other suitable deposition process, or a combination of the foregoing. After the conformal metal layer is formed, a planarization process (e.g., a chemical mechanical planarization (CMP) process is performed to remove portions of the conformal metal layer extending past an upper surface of the second ILD layer 302. The planarization process results in the plurality of contact wires 209 and the plurality of shielding wires 211 having upper surfaces that are level with one another. In some embodiments, vias 212 beneath the first wire level 122 are formed concurrently with the first wire level 122 using a dual-damascene process.

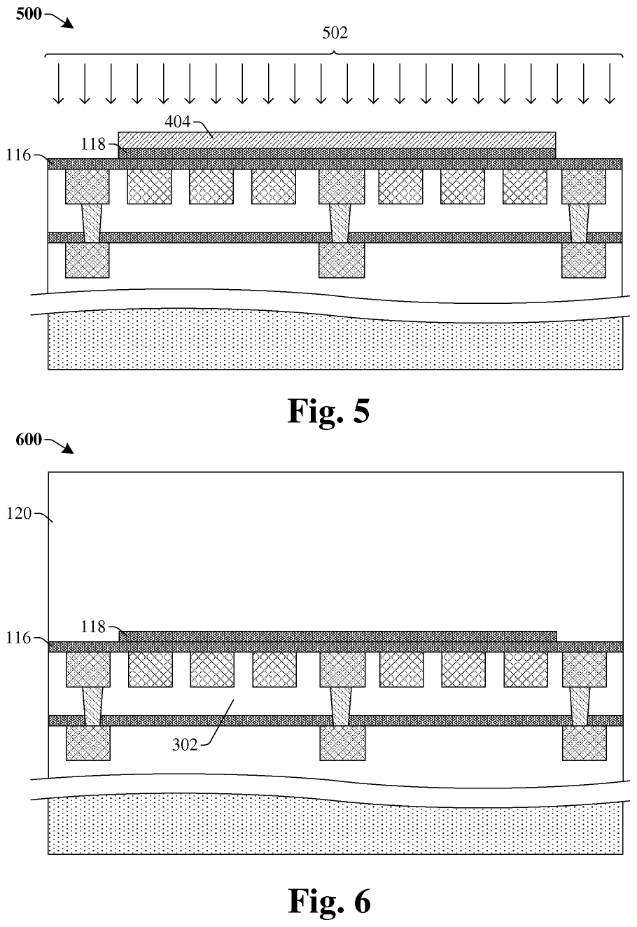

As shown in the cross-sectional view 400 of FIG. 4, the first etch stop layer 116, a first conformal etch stop layer 402, and a first masking layer 404 overlying the first conformal etch stop layer 402 are formed over the second ILD layer 302 and the first wire level 122. In some embodiments, the first etch stop layer 116, and the first conformal etch stop layer 402 are or comprise an insulative material, such as silicon nitride (Si₃N₄), silicon carbide (SiC), or the like. In some embodiments, the first etch stop layer 116 comprises a first material (e.g., silicon nitride or the like) and the first conformal etch stop layer 402 comprises a second material (e.g., silicon carbide or the like) that is different from the first material. The first material and the second material may be different so the patterning of the first conformal etch stop layer 402 discussed hereafter (see FIG. 5) may be performed using an etch process selective to the first material. In some embodiments, the first masking layer 404 is a photoresist.

The first etch stop layer 116, and the first conformal etch stop layer 402 may, for example, be formed using CVD, PVD, ALD, or the like. The first masking layer 404 may, for example, be formed using CVD, PVD, ALD, a spin-on process, or the like. The first masking layer 404 is then patterned, thereby covering portions of the first conformal etch stop layer 402 corresponding to the second etch stop layer (see 118 of FIG. 1) to be formed hereafter. In some embodiments, the first masking layer 404 is or comprises a photoresist and/or the first masking layer 404 is patterned using photolithography.

As shown in the cross-sectional view 500 of FIG. 5, after the first masking layer 404 is patterned, a first etching process 502 is performed on the first conformal etch stop layer (see 402 of FIG. 4) with the first masking layer 404 in place. The first etching process 502 removes portions of the first conformal etch stop layer (see 402 of FIG. 4) exposed by the first masking layer 404, exposing an upper surface of the first etch stop layer 116 and leaving the second etch stop layer 118 beneath the first masking layer 404. In some embodiments, the first etching process 502 is a dry etching process. In embodiments where the first etch stop layer 116 and the first conformal etch stop layer (see 402 of FIG. 4) are or comprise different materials, the first etching process 502 may be a single etching process selective to the material of the first etch stop layer 116. The first masking layer 404 is then removed.

As shown in the cross-sectional view 600 of FIG. 6, the ILD layer 120 is formed over the first etch stop layer 116 and the second etch stop layer 118. In some embodiments, the ILD layer 120 is or comprises an insulator, such as silicon dioxide (SiO₂) or the like. The ILD layer 120, in some embodiments, is a same material as the second ILD layer 302. The ILD layer 120 may, for example, be formed using CVD, PVD, ALD, or the like.

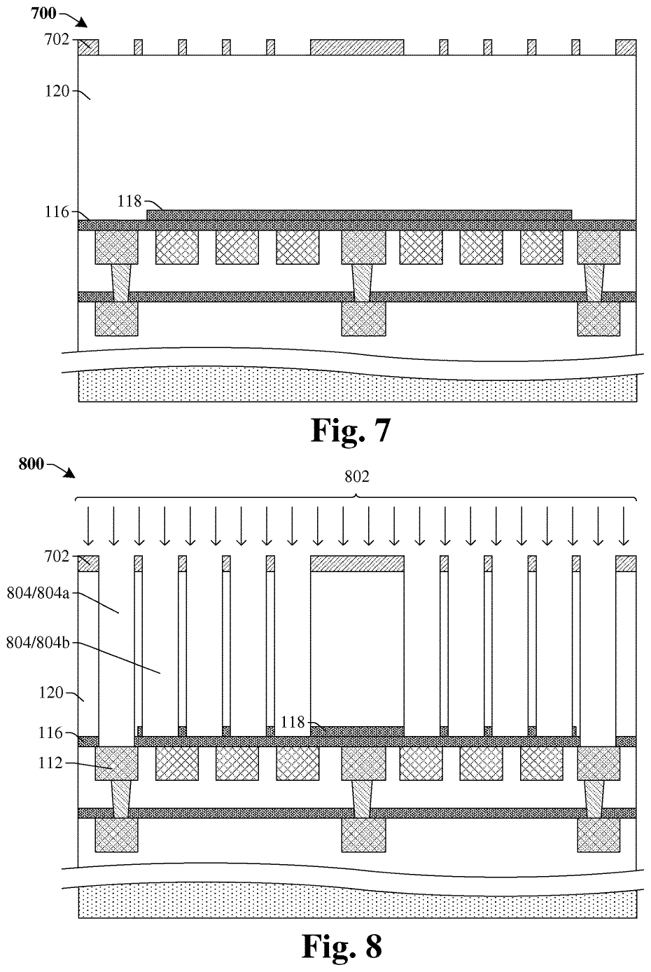

As shown in the cross-sectional view 700 of FIG. 7, a second masking layer 702 is formed over the ILD layer 120. The second masking layer 702 may, for example, be formed using CVD, PVD, ALD, a spin-on process, or the like. The second masking layer 702 is then patterned, thereby covering portions of the ILD layer 120 corresponding to the plurality of protrusions to be formed hereafter. In some embodiments, the second masking layer 702 is or comprises a photoresist and/or the second masking layer 702 is patterned using photolithography.

As shown in the cross-sectional view 800 of FIG. 8, after the second masking layer 702 is patterned, a second etching process 802 is performed on the ILD layer 120 with the second masking layer 702 in place. The second etching process 802 removes portions of the ILD layer 120 exposed by the second masking layer 702, forming trenches 804 in the ILD layer 120. The trenches 804 further extend through either the first etch stop layer 116 or the second etch stop layer 118, based on their positioning over the second etch stop layer 118. That is, openings directly above the second etch stop layer 118 (e.g., second trenches 804b) extend into the second etch stop layer 118, while openings directly above where the first etch stop layer 116 contacts the ILD layer 120 (e.g., first trenches 804a) expose upper surfaces of the plurality of contact wires 209. In some embodiments, the second etching process 802 is a dry etching process. In some embodiments, the second etching process 802 is a single etching process, where the etch rate of the second etching process 802 through the ILD layer 120 is greater than the etch rate of the second etching process 802 through the first etch stop layer 116 or the second etch stop layer 118. The second masking layer 702 is then removed.

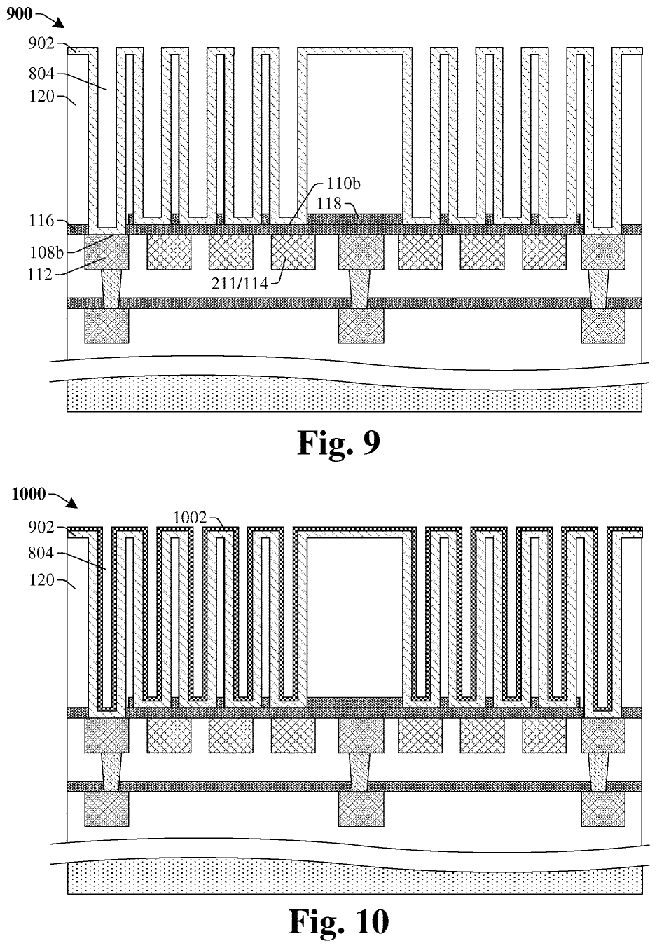

As shown in the cross-sectional view 900 of FIG. 9, a second conformal metal layer 902 is formed over the ILD layer 120 and in the trenches 804. In some embodiments, the second conformal metal layer 902 is formed using ALD, PVD, CVD, electrochemical plating, electroless plating, some other suitable deposition process, or a combination of the foregoing. In some embodiments, the second conformal metal layer 902 is or comprises a conductive material, such as copper (Cu), titanium (Ti), aluminum (Al), the like, or a combination of the foregoing. The second conformal metal layer 902 has both the first bottom surface 108b extending to and contacting the contact wire 112 and the second bottom surface 110b directly over a shielding wire of the plurality of shielding wires 211.

As shown in the cross-sectional view 1000 of FIG. 10, a conformal intermetal dielectric layer 1002 is formed over the second conformal metal layer 902 and in the trenches 804. In some embodiments, the conformal intermetal dielectric layer 1002 is formed using ALD, PVD, CVD, some other suitable deposition process, or a combination of the foregoing. In some embodiments, the conformal intermetal dielectric layer 1002 is or comprises an insulative material such as silicon dioxide (SiO₂), hafnium oxide (Ha₂O₃), a high-k dielectric, or the like. The conformal intermetal dielectric layer 1002 covers upper surfaces and inner sidewalls of the second conformal metal layer 902.

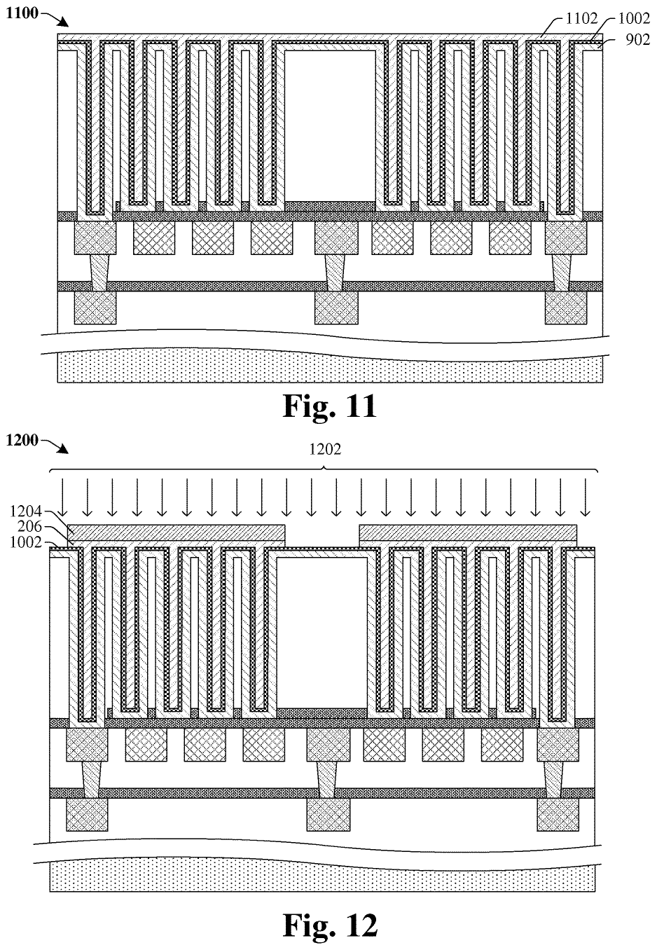

As shown in the cross-sectional view 1100 of FIG. 11, a third conformal metal layer 1102 is formed over the conformal intermetal dielectric layer 1002, filling the trenches (see 804 of FIG. 10). In some embodiments, the third conformal metal layer 1102 is formed using ALD, PVD, CVD, electrochemical plating, electroless plating, some other suitable deposition process, or a combination of the foregoing. In some embodiments, the third conformal metal layer 1102 is or comprises a conductive material, such as copper (Cu), titanium (Ti), aluminum (Al), the like, or a combination of the foregoing. The third conformal metal layer 1102 covers upper surfaces and inner sidewalls of the conformal intermetal dielectric layer 1002.

As shown in the cross-sectional view 1200 of FIG. 12, a third masking layer 1204 is formed over the third conformal metal layer (see 1102 of FIG. 11). The third masking layer 1204 may, for example, be formed using CVD, PVD, ALD, a spin-on process, or the like. The third masking layer 1204 is then patterned, thereby covering portions of the third conformal metal layer (see 1102 of FIG. 11) corresponding to the plurality of protrusions to be formed hereafter. In some embodiments, the third masking layer 1204 is or comprises a photoresist and/or the third masking layer 1204 is patterned using photolithography.

After the third masking layer 1204 is patterned, a third etching process 1202 is performed on the third conformal metal layer (see 1102 of FIG. 11) with the third masking layer 1204 in place. The third etching process 1202 removes portions of the third conformal metal layer (see 1102 of FIG. 11) exposed by the third masking layer 1204, resulting in the top metal layer 206 remaining beneath the third masking layer 1204 and exposing the conformal intermetal dielectric layer 1002. In some embodiments, the third etching process 1202 is a dry etching process. The third masking layer 1204 is then removed.

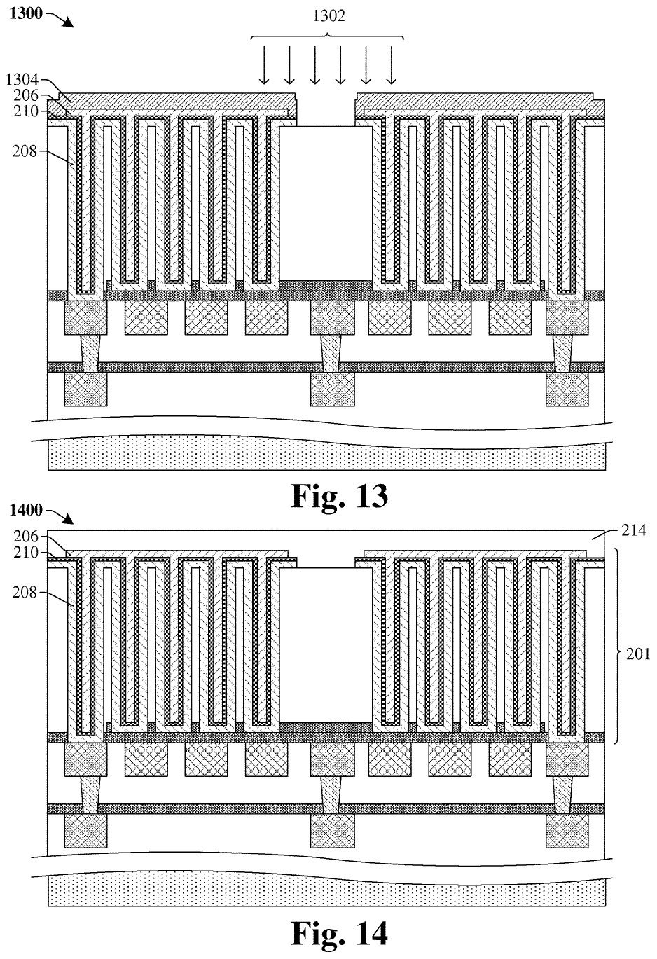

As shown in the cross-sectional view 1300 of FIG. 13, a fourth masking layer 1304 is formed over the top metal layer 206 and the conformal intermetal dielectric layer (see 1002 of FIG. 12). The fourth masking layer 1304 may, for example, be formed using CVD, PVD, ALD, a spin-on process, or the like. The fourth masking layer 1304 is then patterned, thereby covering portions of the top metal layer 206 and the conformal intermetal dielectric layer (see 1002 of FIG. 12) corresponding to the plurality of capacitors 201 to be formed hereafter. In some embodiments, the fourth masking layer 1304 is or comprises a photoresist and/or the fourth masking layer 1304 is patterned using photolithography.

After the fourth masking layer 1304 is patterned, a fourth etching process 1302 is performed on the second conformal metal layer (see 902 of FIG. 11) with the fourth masking layer 1304 in place. The fourth etching process 1302 removes portions of the conformal intermetal dielectric layer (see 1002 of FIG. 12) and the second conformal metal layer (see 902 of FIG. 11) exposed by the fourth masking layer 1304, resulting in intermetal dielectric layer 210 and the bottom metal layer 208 remaining beneath the fourth masking layer 1304. In some embodiments, the third etching process 1202 is a dry etching process. The fourth masking layer 1304 is then removed.

As shown in the cross-sectional view 1400 of FIG. 14, an additional ILD layer of the plurality of ILD layers 214 is formed over the plurality of capacitors 201. In some embodiments, the additional ILD layer is or comprises an insulator, such as silicon dioxide (SiO₂) or the like. The additional ILD layer, in some embodiments, is a same material as the second ILD layer 302. The additional ILD layer may, for example, be formed using CVD, PVD, ALD, or the like.

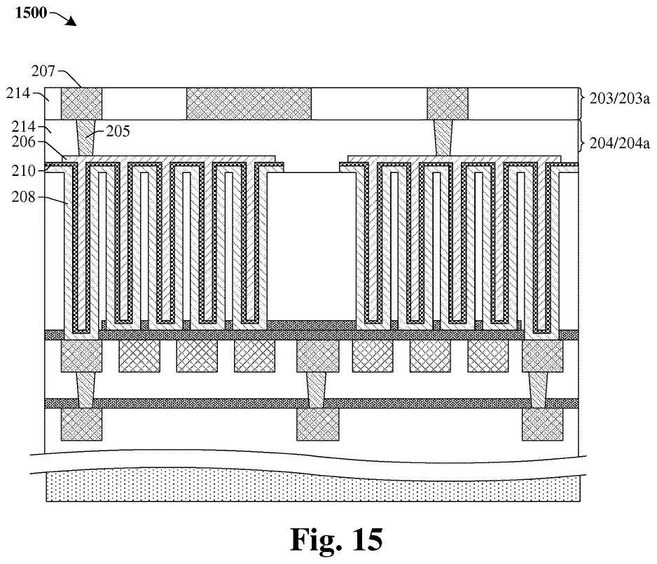

As shown in the cross-sectional view 1500 of FIG. 15, the second via level 204a and the second wire level 203a are formed in the plurality of ILD layers 214. In some embodiments, the vias 205 and the wires 207 of the second via level 204a and the second wire level 203a are or comprise a conductor, such as copper (Cu), titanium (Ti), aluminum (Al), heavily doped polysilicon, or the like. The vias 205 and the wires 207, in some embodiments, are a same material as the contact wire 112. The vias 205 and the wires 207 may, for example, be formed using a combination of etching and CVD, PVD, ALD, damascene processes, a double damascene process, or the like.

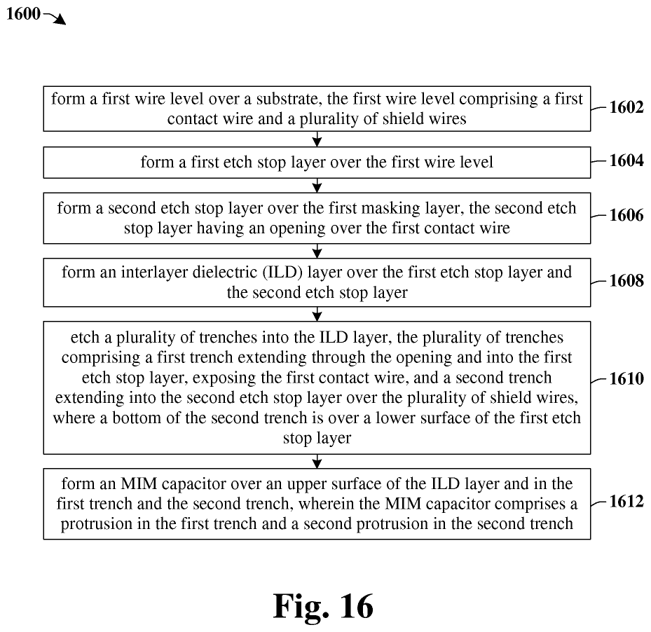

FIG. 16 illustrates a flowchart of some embodiments of a method of forming capacitors with a partial bottom landing on the contact wires. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1602, a first wire level is formed over a substrate, the first wire level comprising a first contact wire and a plurality of shield wires. See, for example, FIG. 3.

At 1604, a first etch stop layer is formed over the first wire level. See, for example, FIG. 4.

At 1606, a second etch stop layer is formed over the first masking layer, where the second etch stop layer has an opening over the first contact wire. See, for example, FIGS. 4-5.

At 1608, an interlayer dielectric (ILD) layer is formed over the first etch stop layer and the second etch stop layer. See, for example, FIG. 6.

At 1610, a plurality of trenches are etched into the ILD layer, where the plurality of trenches comprise a first trench extending through the opening and into the first etch stop layer, exposing the first contact wire, and a second trench extending into the second etch stop layer over the plurality of shield wires, where a bottom of the second trench is over a lower surface of the first etch stop layer. See, for example, FIGS. 7-8.

At 1612, a metal-insulator-metal (MIM) capacitor is formed over an upper surface of the ILD layer and in the first trench and the second trench, wherein the MIM capacitor comprises a protrusion in the first trench and a second protrusion in the second trench. See, for example, FIGS. 9-13.

Some embodiments relate to an integrated device, including a first contact wire comprising an upper surface over a substrate; a plurality of shielding wires level with the first contact wire and having upper surfaces that are level with the upper surface of the first contact wire; and a first capacitor having an upper layer and a plurality of protrusions including a first protrusion and a second protrusion extending from the upper layer in a first direction towards the shielding wires; wherein the first protrusion extends to the upper surface of the first contact wire; and wherein the second protrusion is over and separated from the shielding wires in the first direction.

Other embodiments relate to an integrated device, including a first wire level overlying a substrate; contact wires extending through the first wire level in a first direction; shielding wires extending through the first wire level parallel to the contact wires; a plurality of metal-insulator-metal (MIM) capacitors overlying the first wire level and respectively comprising upper layers, first protrusions, and second protrusions, where the first protrusions and the second protrusions are separated in a second direction perpendicular to the first direction; wherein the first protrusions of the plurality of MIM capacitors extend to the contact wires; and wherein the second protrusions of the plurality of MIM capacitors are spaced from the contact wires in the first direction.

Yet other embodiments relate to a method of forming an integrated device, including forming a first wire level over a substrate, the first wire level having a first contact wire and a plurality of shield wires; forming a first etch stop layer over the first wire level; forming a second etch stop layer over the first etch stop layer, the second etch stop layer having an opening over the first contact wire; forming an interlayer dielectric (ILD) layer over the first etch stop layer and the second etch stop layer; etching a plurality of trenches into the ILD layer, the plurality of trenches having a first trench extending through the opening and into the first etch stop layer, exposing the first contact wire, and a second trench extending into the second etch stop layer over the plurality of shield wires, where a bottom of the second trench is over a lower surface of the first etch stop layer; and forming an MIM capacitor over an upper surface of the ILD layer and in the first trench and the second trench, wherein the MIM capacitor has a protrusion in the first trench and a second protrusion in the second trench.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a first contact wire comprising an upper surface over a substrate;
a plurality of shielding wires level with the first contact wire and having upper surfaces that are level with the upper surface of the first contact wire; and
a first capacitor comprising an upper layer and a plurality of protrusions comprising a first protrusion and a second protrusion extending from the upper layer in a first direction towards the plurality of shielding wires;
wherein the first protrusion extends to the upper surface of the first contact wire; and
wherein the second protrusion is over and separated from the plurality of shielding wires in the first direction.

2. The integrated device of claim 1, further comprising:
a wire level overlying the first capacitor; and
a via coupling a wire of the wire level to the first capacitor.

3. The integrated device of claim 1, wherein a bottom surface of the first protrusion is covered by the upper surface of the first contact wire.

4. The integrated device of claim 1, further comprising a first etch stop layer and a second etch stop layer overlying the first etch stop layer, wherein the first protrusion extends through the first etch stop layer and the second protrusion is spaced from the plurality of shielding wires by the first etch stop layer.

5. The integrated device of claim 4, wherein the second etch stop layer has a sidewall facing the first protrusion, wherein the sidewall is separated from the first protrusion.

6. The integrated device of claim 4, wherein the second protrusion extends into the second etch stop layer.

7. The integrated device of claim 4, wherein the first protrusion is spaced from the second etch stop layer and the second protrusion is directly contacting the second etch stop layer.

8. An integrated device, comprising:
a first wire level overlying a substrate;
contact wires extending through the first wire level in a first direction;
shielding wires extending through the first wire level substantially parallel to the contact wires; and
a plurality of metal-insulator-metal (MIM) capacitors overlying the first wire level and respectively comprising upper layers, first protrusions, and second protrusions, wherein the first protrusions and the second protrusions are separated in a second direction perpendicular to the first direction;
wherein the first protrusions of the plurality of MIM capacitors extend to the contact wires; and
wherein the second protrusions of the plurality of MIM capacitors are spaced from the contact wires in the second direction.

9. The integrated device of claim 8, wherein a first MIM capacitor of the plurality of MIM capacitors comprises a third protrusion extending over the shielding wires;
wherein a first protrusion of the first MIM capacitor has a first depth measured from an upper layer of the first MIM capacitor;
wherein a second protrusion of the first MIM capacitor has a second depth measured from the upper layer that is less than the first depth; and
wherein the third protrusion of the first MIM capacitor has a third depth measured from the upper layer that is substantially equal to the second depth.

10. The integrated device of claim 8, wherein a first MIM capacitor of the plurality of MIM capacitors has a first number of protrusions, and a second MIM capacitor of the plurality of MIM capacitors has a second number of protrusions different from the first number of protrusions.

11. The integrated device of claim 8, wherein a first MIM capacitor of the plurality of MIM capacitors has a first spacing between a first protrusion and a second protrusion of the first MIM capacitor, and a second MIM capacitor of the plurality of MIM capacitors has a second spacing between a first protrusion and a second protrusion of the second MIM capacitor, wherein the first spacing is greater than the second spacing.

12. The integrated device of claim 8, further comprising one or more additional wires in the first wire level between a first MIM capacitor of the plurality of MIM capacitors and a second MIM capacitor of the plurality of MIM capacitors; wherein the one or more additional wires are configured to propagate one or more signals in the first direction.

13. The integrated device of claim 8, further comprising a first etch stop layer extending over the first wire level and a second etch stop layer extending over the first etch stop layer, wherein the second etch stop layer is spaced from the first protrusions in the first direction and the second direction.

14. The integrated device of claim 13, wherein an upper surface of the first etch stop layer is contacting sidewalls of the first protrusions; and wherein an upper surface of the second etch stop layer is contacting sidewalls of the second protrusions and is spaced from sidewalls of the first protrusions.

15. A method of forming an integrated device, comprising:
forming a first wire level over a substrate, the first wire level comprising a first contact wire and a plurality of shield wires;
forming a first etch stop layer over the first wire level;
forming a second etch stop layer over the first etch stop layer, the second etch stop layer having an opening over the first contact wire;
forming an interlayer dielectric (ILD) layer over the first etch stop layer and the second etch stop layer;
etching a plurality of trenches into the ILD layer, the plurality of trenches comprising a first trench extending through the opening and into the first etch stop layer, exposing the first contact wire, and a second trench extending into the second etch stop layer over the plurality of shield wires, where a bottom of the second trench is over a lower surface of the first etch stop layer; and
forming a metal-insulator-metal (MIM) capacitor over an upper surface of the ILD layer and in the first trench and the second trench, wherein the MIM capacitor comprises a protrusion in the first trench and a second protrusion in the second trench.

16. The method of claim 15, wherein forming the MIM capacitor further comprises:
forming a first conformal metal layer over the ILD layer and in the first trench and the second trench;
forming a first conformal intermetal dielectric layer over the first conformal metal layer and in the first trench and the second trench;
forming a second conformal metal layer over the first conformal intermetal dielectric layer, filling the first trench and the second trench; and
etching the first conformal metal layer, the first conformal intermetal dielectric layer, and the second conformal metal layer to delineate a bottom metal layer, an intermetal dielectric, and a top metal layer.

17. The method of claim 15, wherein etching of the plurality of trenches is performed using a single etching process.

18. The method of claim 17, wherein the single etching process has first etch rate when etching through the ILD layer, and a second etch rate when etching through the first etch stop layer and second etch stop layer, and the first etch rate is greater than the second etch rate.

19. The method of claim 15, wherein the first trench has a first depth measured from an upper surface of the ILD layer and the second trench has a second depth measured from the upper surface of the ILD layer, and wherein the first depth is greater than the second depth.

20. The method of claim 15, wherein the second trench extends through the second etch stop layer, but is separated from the shielding wires by the first etch stop layer.
